(19) United States
(12) Patent Application Publication
(10) Pub. No.: US 2014/0151718 A1
(43) Pub. Date: Jun. 5, 2014

(54) SEMICONDUCTOR DEVICE AND MANUFACTURING METHOD THEREOF

(71) Applicant: MITSUBISHI ELECTRIC CORPORATION, Tokyo (JP)

(72) Inventor: Tatsunori YANAGIMOTO, Tokyo (JP)

(73) Assignee: MITSUBISHI ELECTRIC CORPORATION, Tokyo (JP)

(21) Appl. No.: 13/951,327

(22) Filed: Jul. 25, 2013

(30) Foreign Application Priority Data
Nov. 30, 2012 (JP) 2012-261829

(51) Int. Cl. H01L 23/42

(52) U.S. Cl. CPC H01L 23/42
USPC 257/77; 257/676; 438/123

(57) ABSTRACT

A semiconductor device according to the present invention includes a die pad, a semiconductor element joined to an upper surface of the die pad, and a resin sheet making close contact with a lower surface of the die pad, wherein the semiconductor element is resin-sealed together with the die pad and the resin sheet, wherein a recess is formed in the lower surface of the die pad, and a part of the resin sheet is filled into the recess bring the resin sheet into close contact with the lower surface of the die pad including an inside of the recess.

### BACKGROUND OF THE INVENTION

1. Field of the Invention

The present invention relates to a semiconductor device and a manufacturing method thereof. More specifically, the present invention relates to a semiconductor device on which a semiconductor element for electric power is mounted.

2. Description of the Background Art

A semiconductor device for electric power is used for controlling and rectifying relatively large electric power in a railroad vehicle, a hybrid car, an electric car, a household electric appliance, industrial equipment, and the like. Therefore, a semiconductor element used for the semiconductor device for electric power is required to be energized at a current density above 100 A/cm². As semiconductor materials in place of silicon (Si), silicon carbide (SiC) and gallium nitride (GaN) which are a wide bandgap semiconductor material have been noted in recent years. In particular, a SiC semiconductor element can be operated at a current density above 500 A/cm². In addition, the SiC semiconductor element can be stably operated at a high temperature from 150° C. to 300° C., and is expected as a semiconductor material which can cope with both high-current density operation and high-temperature operation.

In a structure of such a semiconductor device for electric power, for example, a plurality of semiconductor elements are arranged on an upper surface of a die pad, and an insulating resin sheet having high heat dissipation properties (hereinafter, simply referred to as a resin sheet) makes close contact with a lower surface of the die pad. Further, a lead frame is provided as an external terminal, and the semiconductor element is resin-sealed together with the die pad and the resin sheet. The resin sheet typically has a higher heat conductivity than a sealing resin used for the resin sealing (e.g., see Japanese Patent Application Laid-Open No. 2004-172239).

The wide bandgap semiconductor is required to use the resin sheet having high heat dissipation properties and insulation properties in order to be suitable for the high-current density and high-temperature operation. To enhance the heat dissipation properties of the resin sheet, generally, a filler is highly filled into the insulating resin. However, a content ratio of an adhering resin is reduced to lower an adhesion strength thereof. When the adhesion strength is lowered to separate the resin sheet from the lower surface of the die pad on which the semiconductor elements are arranged, potential gradient concentrates onto the boundary between a separated portion and a non-separated portion to cause partial discharge. Consequently, a dielectric voltage of the semiconductor device is lowered.

Since the semiconductor device changes its temperature with operation, heat stress is caused between members having different linear expansion coefficients to separate the members at an interface therebetween. Accordingly, there is proposed a semiconductor device which improves contactivity between the resin sheet and the die pad on which a semiconductor element producing heat is arranged (e.g., see Japanese Patent Application Laid-Open No. 2009-302526).

In a structure described in Japanese Patent Application Laid-Open No. 2004-172239, the resin sheet, the die pad, and an inner lead are resin-sealed together by a transfer mold process, for example. The resin sheet is half-cured in order to hold the contactivity between the resin sheet and the die pad. The heat at the time of resin sealing volatilizes a solvent component in the resin sheet, and a gap may be caused in resin sealing. When the gap is caused at an interface between the die pad and the resin sheet, not only heat dissipation properties but also a dielectric voltage of the semiconductor device is lowered.

In addition, in a structure described in Japanese Patent Application Laid-Open No. 2009-302526, the resin sheet and the die pad on which a semiconductor element is arranged are brought into close contact with each other by a compression mold process, and are then resin-sealed by the transfer mold process. Since the transfer mold process is performed after the compression mold process, the number of steps is increased to lower productivity. Further, the number of times to handle the lead frame on which semiconductor elements and wires are mounted is increased to lower yield.

### SUMMARY OF THE INVENTION

An object of the present invention is to provide a semiconductor device having high contactivity between a resin sheet and a die pad on which a semiconductor element is arranged as well as high heat dissipation properties, and a manufacturing method thereof.

A semiconductor device according to the present invention includes a die pad, a semiconductor element joined to an upper surface of the die pad, and a resin sheet making close contact with a lower surface of the die pad. The semiconductor element is resin-sealed together with the die pad and the resin sheet. A recess is formed in the lower surface of the die pad. A part of the resin sheet is filled into the recess so that the resin sheet makes close contact with the lower surface of the die pad including an inside of the recess.

In the semiconductor device according to the present invention, the recess is provided in the lower surface of the die pad. Thus, a contact area of the die pad with the resin sheet can be larger as compared to a structure in which the recess is not provided in the lower surface of the die pad. The contactivity between the die pad and the resin sheet can thus be improved. The larger contact area of the die pad with the resin sheet improves heat dissipation properties. The improved contactivity between the die pad and the resin sheet can prevent the separation of the resin sheet. Thus, the reliability of the semiconductor device can be improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view of a semiconductor device according to a first preferred embodiment;

FIG. 2 shows a bottom view and a side view of the semiconductor device according to the first preferred embodiment;

FIG. 3 shows a plan view and a cross-sectional view of the semiconductor device according to the first preferred embodiment;

FIGS. 4A, 4B and 4C are partial cross-sectional views of the semiconductor device according to the first preferred embodiment;

FIGS. 5A, 5B, 5C and 5D are diagrams showing a manufacturing method of the semiconductor device according to the first preferred embodiment;

FIG. 6 is a diagram showing the structure of a die pad provided in the semiconductor device according to a second preferred embodiment; and

FIG. 7 is a diagram showing the structure of the die pad provided in the semiconductor device according to a third preferred embodiment.

### DESCRIPTION OF THE PREFERRED EMBODIMENTS

### First Preferred Embodiment

### Structure

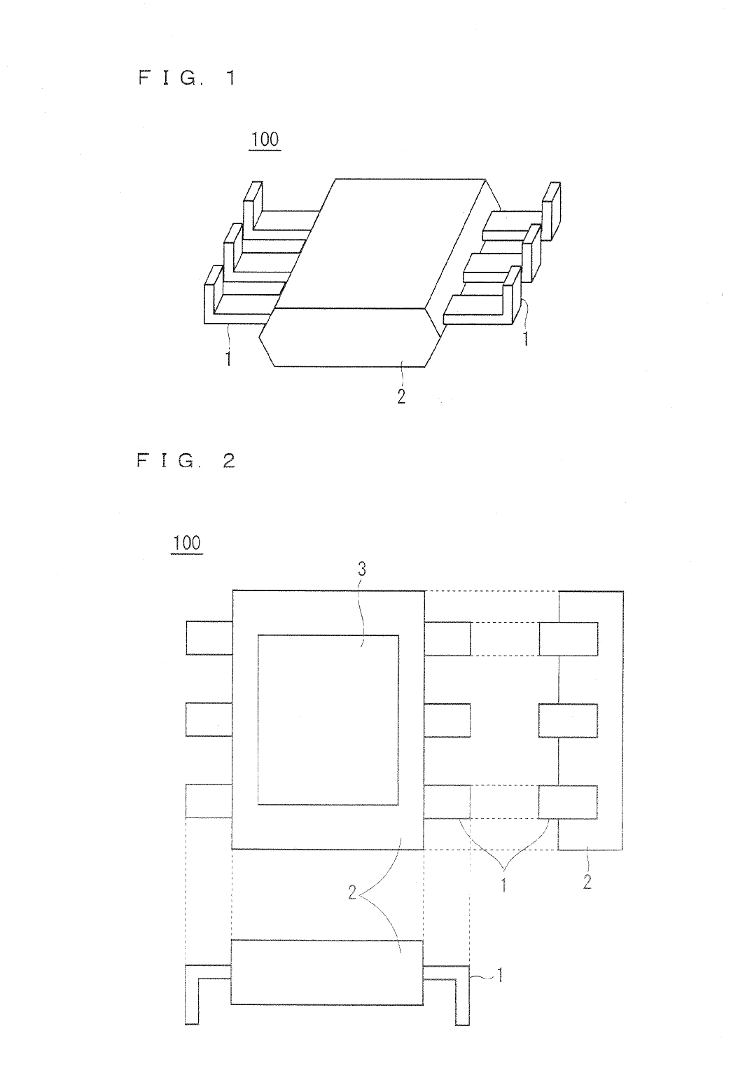

FIG. 1 shows a perspective view of a semiconductor device 100 according to this preferred embodiment. FIG. 2 shows a bottom view and a side view of the semiconductor device 100 according to this preferred embodiment. A package of the semiconductor device 100 is resin-sealed by a sealing resin 2, and a lead frame 1 projects from side surfaces thereof. At the bottom surface of the semiconductor device 100, a metal plate 3 made of copper foil, for example, has its one principal plane exposed. The metal plate 3 may be made of a material having a higher heat conductivity than the sealing resin 2, and may be made of aluminum, for example. As described later, a resin sheet makes close contact with the other principal plane of the metal plate 3. The sealing resin is an epoxy resin, for example.

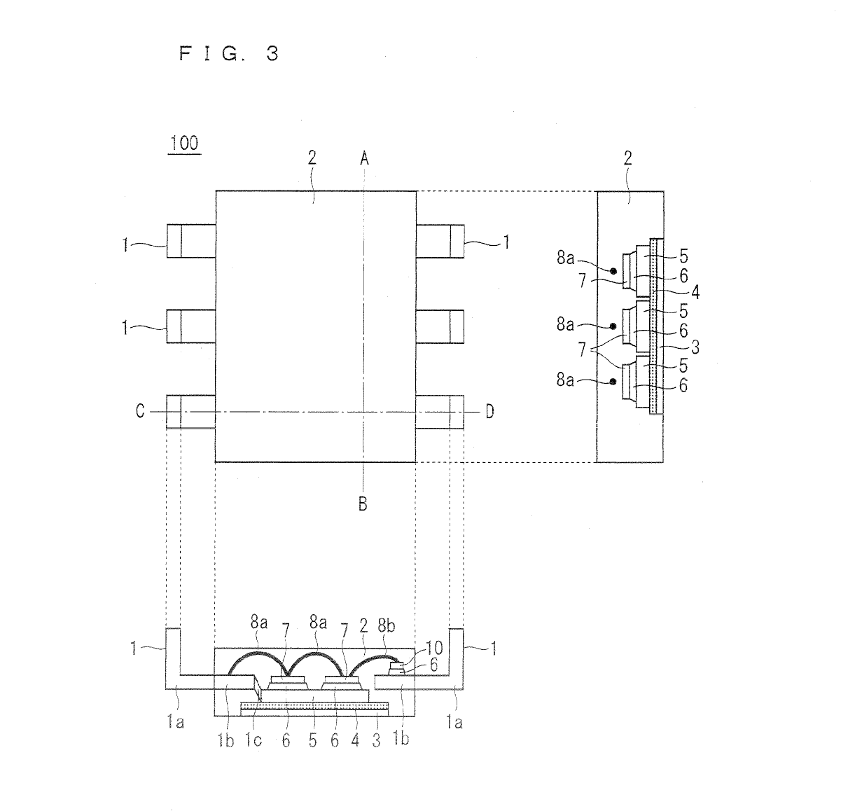

FIG. 3 shows a top view and a cross-sectional view taken along lines AB and CD of the semiconductor device 100. The semiconductor device 100 includes a plurality of lead frames 1. As shown in the cross-sectional view taken along line CD, the left lead frame 1 is integral with a die pad 5. That is, the left lead frame 1 includes an outer lead 1a which is not resin-sealed by the sealing resin 2, an inner lead 1b which is resin-sealed by the sealing resin 2, the die pad 5, and a step 1c connecting the die pad 5 and the inner lead. The inner lead 1b and the die pad 5 are not necessarily required to be connected via the step 1c.

A semiconductor element 7 is joined to an upper surface of the die pad 5 by a joining portion 6 with solder or silver paste. Further, the semiconductor element 7 joined to the upper surface of the die pad 5 is, for example, a semiconductor element for electric power, and is FWD (Free Wheeling Diode), IGBT (Insulated Gate Bipolar Transistor), MOSFET (Metal Oxide Semiconductor Field Effect Transistor), and SBD (Schottky Barrier Diode). In this preferred embodiment, as the semiconductor element 7, IGBT and FWD as a SiC semiconductor element which is a preferred application example of the present invention are joined in parallel to the upper surface of the die pad 5.

In the lead frame 1 which is not directly connected to the die pad 5, an IC (integrated circuit) semiconductor element 10 is joined to an upper surface of the inner lead 1b via the joining portion 6. The IC semiconductor element 10 is, for example, a logic chip. The IC semiconductor element 10 controls an operation of the semiconductor element 7.

The semiconductor elements 7 or the semiconductor element 7 and the inner lead 1b are connected by a thick bonding wire 8a made of, for example, gold or aluminum. The thick bonding wire 8a is made of aluminum, copper, or an alloy thereof. In addition, the IC semiconductor element 10 and the inner lead 1b are connected by a thin bonding wire 8b made of gold, copper, or an alloy thereof having a smaller wire diameter than the thick bonding wire 8a.

Note that a plurality of semiconductor elements 7 and IC semiconductor elements 10 may be provided according to the function of the semiconductor device 100.

A surface of the package of the semiconductor device 100 is covered by the sealing resin 2. That is, the semiconductor element 7 and the IC semiconductor element 10 are resin-sealed by the sealing resin 2 together with the die pad 5 and a resin sheet 4. In addition, the metal plate 3 is exposed from a back side of the semiconductor device 100. Since the metal plate 3 protects the resin sheet 4 from damage, the resin sheet 4 can maintain high insulation properties. This damage is considered to be caused, for example, when the semiconductor device 100 is screwed into an external heat sink (not shown) while a foreign substance is caught between the semiconductor device 100 and the external heat sink.

When the above damage is unlikely to be caused, the metal plate 3 may not be provided. In this case, the resin sheet 4 is exposed from the back side of the semiconductor device 100.

In this preferred embodiment, the metal plate 3 is made of copper foil having a thickness of 0.1 mm. However, as described later, when the metal plate 3 onto which the resin sheet 4 is bonded is resin-sealed, the metal plate 3 may only have strength to the extent that its structure is not deformed when conveyed into a die cavity, and have a thickness of 0.075 mm or more. For example, the copper foil having a thickness below 0.05 mm is torn or deformed.

A lower surface of the die pad 5 makes close contact with an upper surface of the resin sheet 4. An area of the resin sheet 4 is larger than an area of the die pad 5. A thickness of the resin sheet 4 is, e.g., 0.1 mm.

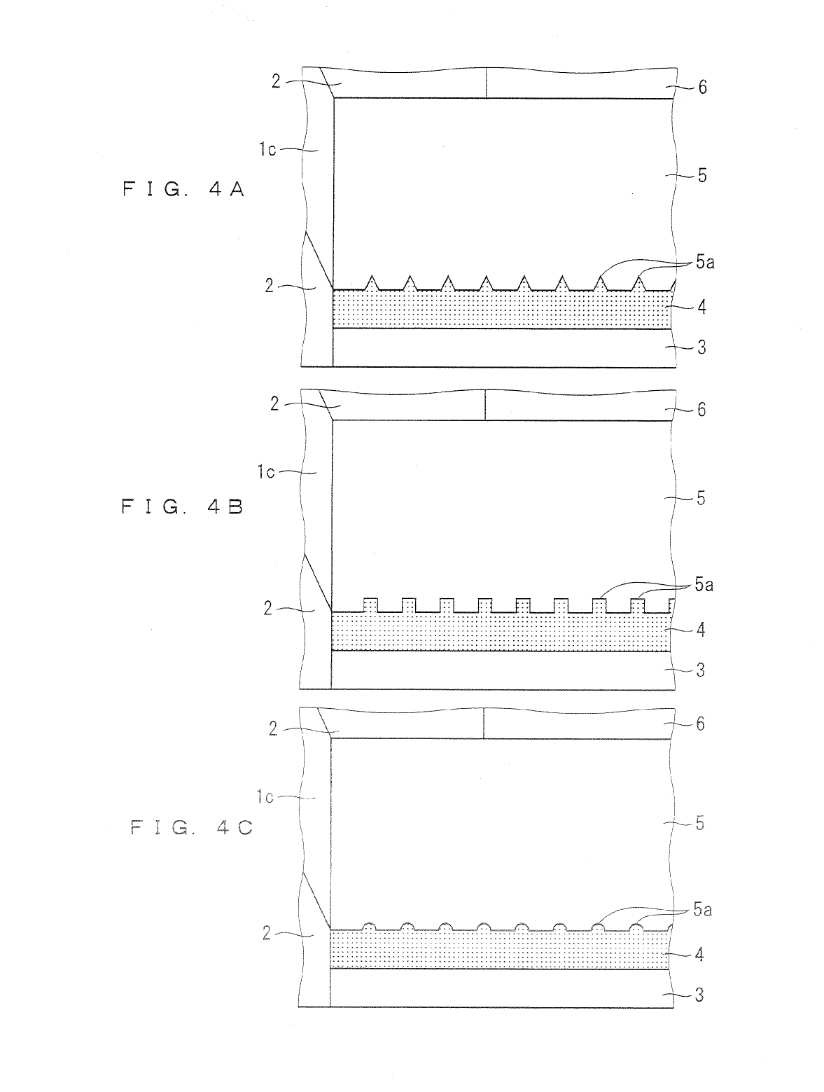

As shown in FIG. 4A, a recess 5a having a V-shaped cross section is formed in the lower surface of the die pad 5, that is, in a surface making contact with the resin sheet 4. A part of the resin sheet 4 is filled into the recess 5a, and makes close contact with the die pad 5 inside the recess 5a. In this way, the recess 5a increases a contact area of the lower surface of the die pad 5 with the resin sheet 4. The die pad 5 and the resin sheet 4 thus make close contact with each other.

A heat dissipation filler may be mixed into the resin sheet 4. In the resin sheet 4, a density of the filler in the portion filled into the recess 5a that is provided in the lower surface of the die pad may be lower than a density of the filler in a portion not filled into the recess 5a.

As shown in FIG. 4B, a cross-sectional shape of the recess 5a may be rectangular. In addition, as shown in FIG. 4C, the cross-sectional shape of the recess 5a may be semicircular. As described later, the recess 5a may have any cross-sectional shape as long as the resin sheet 4 can enter the recess 5a.

The recess 5a only needs to have a depth in which the die pad 5 provided with the recess 5a is not easily deformed. When the thinnest portion of the die pad 5 is 0.1 mm or more, the depth of the recess 5a is not limited. For example, when a plate thickness of the die pad 5 is 0.4 mm, the depth of the recess 5a may be 0.3 mm or less.

More preferably, for a shape of the recess 5a, a width of an inside of the recess 5a is larger than a width of an opening of the recess 5a. Such a shape allows the resin sheet 4 filled into the recess 5a to be hard to be separated from the recess 5a. The die pad 5 and the resin sheet 4 can thus make close contact with each other more strongly.

A composition of the resin sheet 4 will be described below. The resin sheet 4 is made by kneading an epoxy resin component and the heat dissipation filler that increases the heat dissipation properties of the resin sheet. The epoxy resin component is a base material, and serves as a binder with the filler and an adhesive of the die pad 5 and the metal plate 3 (hereinafter, referred to as an insulating resin). The thickness of the resin sheet 4 is 0.1 mm. As described later, the thickness of the resin sheet 4 is changed according to heat resistance required for the semiconductor device 100, but is desirably in the range of 0.05 mm to 0.5 mm. The filler contained in the resin sheet 4 will be described in detail. The filler is selected from the group consisting of SiO₂, Al₂O₃, AlN, Si₃N₄, and BN, and is scale-shaped or spherical-shaped. In addition, a particle diameter of the coagulated filler can be from 0.05 mm to about 0.1 mm, but filler particles which have a particle diameter smaller than that are used. In the present invention, the filler is a mixture of the scale-shaped filler and fine particles of about several tens of nanometers. However, a combination of the filler material and the particle diameter is not specified thereto, and a plurality of materials may be combined according to heat resistance required for the semiconductor device 100. In addition, in this preferred embodiment, to increase a heat conductivity of the resin sheet 4, the filler has a volume content of 80%, and a heat conductivity of about 10 W/mK. The filler may have any volume content when it can satisfy heat resistance required for the semiconductor device 100 and heat conductivity required for the resin sheet 4, and actually has a volume content of 50% to 90%. A heat conduction mechanism of the resin sheet 4 will be described. A heat conductivity of the insulating resin alone of the resin sheet 4 is about 0.5 W/mK, and the heat conductivity of the filler is about 80 W/mK. In the resin sheet 4, a contact path of the heat dissipation fillers preferentially and selectively becomes a heat conduction path.

### Manufacturing Method

A method of manufacturing the semiconductor device 100 according to this preferred embodiment will be described. First, a process for manufacturing the lead frame 1 including the die pad 5, the inner lead 1b, the outer lead 1a, and the step 1c will be described. A copper plate cut into a suitable size is subjected to pressing one or a plurality of times to form the lead frame 1 including the die pad 5, the inner lead 1b, the outer lead 1a, and the step 1c. Here, the copper plate may be of an alloy mainly containing copper having a composition of Cu-0.03P-0.1Fe or an alloy having a composition of Cu-0.15Sn. In addition, the copper plate may be of an alloy mainly containing Al like an A5052 material or pure copper. Further, although a thickness of the lead frame 1 is 0.4 mm in the present invention, the lead frame 1 only needs to have a thickness in which pressing is enabled and which is not easily deformed after press forming. For example, the thickness of the lead frame 1 is desirably in the range of 0.1 to 1.5 mm. To improve the soldering ability of the semiconductor element 7, the upper surface of the die pad 5 may be subjected to silver plating or palladium plating.

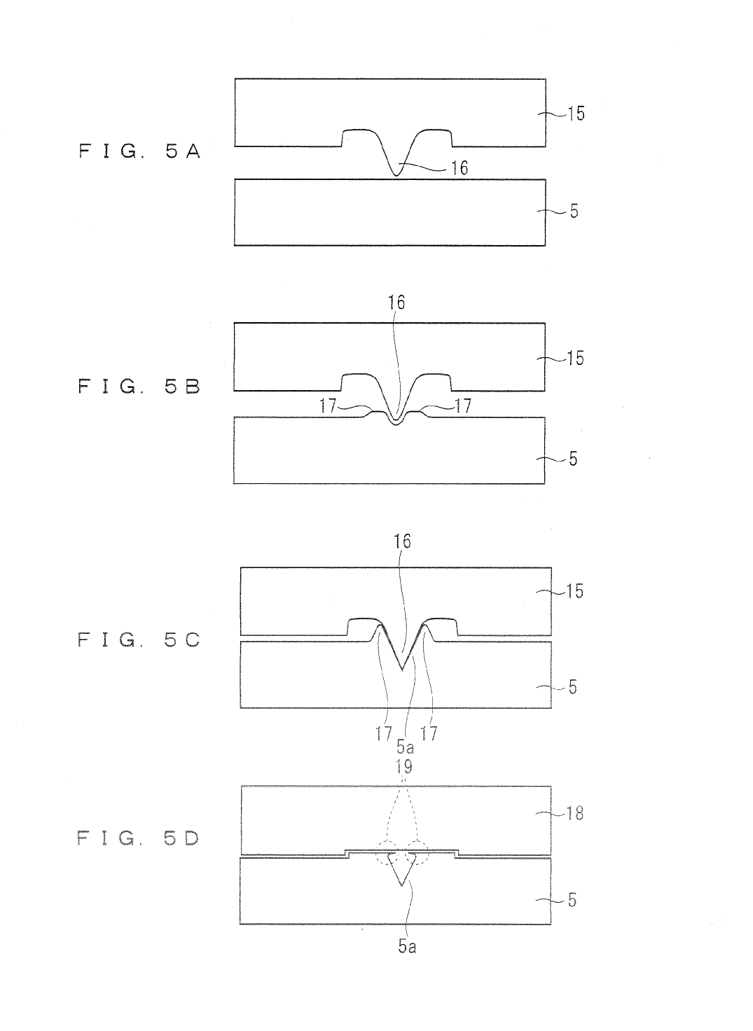

Next, a process for forming the recess 5a in a lower surface of the die pad 5 will be described. FIGS. 5A, 5B, 5C and 5D show a procedure for forming the recess 5a having a V-shaped cross section and in which the width of the inside of the recess 5a is larger than the width of the opening of the recess 5a.

As shown in FIG. 5A, the lower surface of the die pad 5 is subjected to coining by a die 15 with a projection 16 having a V-shaped cross section. In this case, projections 17 are formed near the opening of the recess 5a formed by coining (FIGS. 5B and 5C). The projections 17 formed near the opening of the recess 5a are then subjected to coining again by a flat die 18 to be collapsed (FIG. 5D). As a result, a pawl 19 is formed in the opening of the recess 5a to reduce the width of the opening. By performing coining twice, the recess 5a in which the width of the inside of the recess 5a is larger than the width of the opening of the recess 5a is formed in the lower surface of the die pad 5. The width of the opening of the recess 5a is formed into, e.g., 0.05 mm.

When the width of the inside of the recess 5a is not required to be larger than the width of the opening of the recess 5a, coining by the flat die 18 is omitted.

In addition, the forming of the recess 5a having a rectangular cross section will be described. First, a rectangular recess is formed by half etching. Next, the recess is subjected to coining by a die in which the projection 16 of the die 15 has a rectangular cross section, thereby forming a deeper rectangular recess. At the same time, projections are formed near the opening of the recess. Further, the projections are subjected to coining with the flat die to be collapsed, thereby forming a pawl in the opening.

The semiconductor element 7 is joined to the upper surface of the die pad 5 via the joining portion 6 with solder, for example. In this case, the joining portion 6 is solder. The IC semiconductor element 10 is joined to the upper surface of another lead frame 1.

Next, a contacting process for causing the lower surface of the die pad 5 to make close contact with the resin sheet 4 and a sealing process using the sealing resin 2 will be described. The contacting process and the sealing process are performed at the same time using a mold (not shown).

First, the half-cured resin sheet 4 is arranged in the mold. The mold is held at a high temperature above a melting temperature of the sealing resin 2, e.g., at a temperature above 180° or more. When providing the metal plate 3, the metal plate 3 is arranged between the mold and the resin sheet 4 so as to make contact with a lower surface of the resin sheet 4.

The die pad 5 is arranged on the upper surface of the resin sheet 4 so that the lower surface of the die pad 5 makes contact with the upper surface of the resin sheet 4. At this time, the half-cured resin sheet 4 receives heat from the mold held at high temperature to be melted. Another lead frame 1 which is not connected to the die pad 5 is arranged in a predetermined position of the mold.

The sealing resin 2 is injected into the mold. The sealing pressure of the melted sealing resin 2 presses the die pad 5 onto the resin sheet 4. At this time, the melted resin sheet 4 has suitable flowability, but the filler included in the resin sheet 4 is not melted. Therefore, the melted insulating resin preferentially enters the recess 5a in the lower surface of the die pad 5. Since the opening width of the recess 5a is 0.05 mm, the coagulated filler hardly enters the recess 5a. The density of the filler in the resin sheet 4 is thus relatively increased to increase its heat conductivity.

As described above, a part of the resin sheet 4 is filled into the recess 5a so that the resin sheet 4 makes close contact with the lower surface of the die pad 5 including the inside of the recess. Simultaneously with the contact of the die pad 5 and the resin sheet 4 with each other, the semiconductor element 7 is resin-sealed by the sealing resin 2 together with the die pad 5 and the resin sheet 4. When the metal plate 3 is arranged between the mold and the resin sheet 4, one principal plane of the metal plate 3 is adhered onto the lower surface of the resin sheet 4, and the other principal plane of the metal plate 3 is exposed from the bottom surface of the semiconductor device 100. By the above manufacturing process, the semiconductor device 100 according to this preferred embodiment is manufactured.

### Effect

The semiconductor device 100 according to this preferred embodiment includes the die pad 5, the semiconductor element 7 arranged on the upper surface of the die pad 5, and the resin sheet 4 making close contact with the lower surface of the die pad 5. The semiconductor element 7 is resin-sealed together with the die pad 5 and the resin sheet 4. The recess 5a is formed in the lower surface of the die pad 5. A part of the resin sheet 4 is filled into the recess 5a so that the resin sheet 4 makes close contact with the lower surface of the die pad 5 including the inside of the recess 5a.

Since the recess 5a is provided in the lower surface of the die pad 5, the contact area of the die pad 5 with the resin sheet 4 can be larger as compared to the structure in which the recess is not provided in the lower surface of the die pad 5. The contactivity between the die pad 5 and the resin sheet 4 can thus be improved. In addition, the larger contact area can efficiently conduct heat from the semiconductor element 7 joined onto the die pad 5 to the resin sheet 4 via the die pad 5. That is, the improved heat dissipation properties can hold the semiconductor element 7 in operation at a suitable temperature. For example, when the semiconductor element 7 is a switching semiconductor element, switching loss can be prevented. Further, the improved contactivity between the die pad 5 and the resin sheet 4 can prevent the separation of the resin sheet 4. The reliability of the semiconductor device 100 can thus be improved.

In the semiconductor device 100 according to this preferred embodiment, the cross section of the recess 5a is V-shaped.

Since the cross section of the recess 5a is V-shaped, the forming of the recess 5a becomes easy. Cost reduction can thus be expected in the manufacturing process.

In the semiconductor device 100 according to this preferred embodiment, the width of the inside of the recess 5a is larger than the width of the opening of the recess 5a.

The pawl 19 formed in the opening of the recess 5a allows the resin sheet 4 filled into the recess 5a to be hard to detach from the recess 5a. The contactivity between the die pad 5 and the resin sheet 4 can thus be improved.

In the semiconductor device 100 according to this preferred embodiment, the heat dissipation filler is mixed into the resin sheet 4, and the density of the filler in the portion of the resin sheet 4 filled into the recess 5a is lower than the density of the filler in the rest portion of the resin sheet 4.

Since the density of the filler in the portion of the resin sheet 4 filled into the recess 5a is lower than the density of the filler in the rest portion of the resin sheet 4, the adhesion between the resin sheet 4 and the recess 5a becomes stronger. On the other hand, since the density of the filler in the portion of the resin sheet 4 not filled into the recess 5a is higher than the density of the filler in the portion of the resin sheet 4 filled into the recess 5a, the heat conductivity is excellent for efficiently performing heat release. In addition, since the density of the filler is higher as compared with the case where the recess 5a is not provided, when about the same heat dissipation properties as the case where the recess 5a is not provided is required, the thickness of the resin sheet 4 can be relatively reduced.

In the semiconductor device 100 according to this preferred embodiment, the semiconductor element 7 is a SiC semiconductor element. The SiC semiconductor element which can be operated at a higher temperature than the Si semiconductor element is assumed to produce particularly much heat (e.g., 200° C. or more). By improving the contactivity between the die pad 5 and the resin sheet 4 in the present invention, even when the semiconductor element 7 becomes hot, the separation of the resin sheet 4 from the die pad 5 due to a difference in linear expansion coefficient can be prevented. The reliability of the semiconductor device 100 can thus be improved.

In the method of manufacturing the semiconductor device 100 according to this preferred embodiment includes the steps of: (a) forming the recess 5a in the lower surface of the die pad 5; (b) after the step (a), joining the semiconductor element 7 to the upper surface of the die pad 5; (c) after the step (b), arranging the resin sheet 4 in the mold held at a temperature at which the sealing resin 2 can be melted to arrange the die pad 5 on the upper surface of the resin sheet 4; and (d) after the step (c), injecting the sealing resin 2 into the mold and pressing the lower surface of the die pad 5 onto the resin sheet 4 by a pressure of the sealing resin 2 injected into the mold to fill a part of the resin sheet 4 into the recess 5a so that the resin sheet 4 makes close contact with the lower surface of the die pad 5 including the inside of the recess 5a, and simultaneously, resin-sealing the semiconductor element 7 by the sealing resin 2 together with the die pad 5 and the resin sheet 4.

The contact between the die pad 5 and the resin sheet 4, and the resin sealing are simultaneously performed in one step. Therefore, the semiconductor device 100 according to this preferred embodiment can be manufactured without adding the sealing step as in the conventional technique. The number of times to handle the lead frame 1 on which the semiconductor element 7 or the like is mounted can be reduced to improve the yield.

In the method of manufacturing the semiconductor device 100 according to this preferred embodiment, coining is performed a plurality of times in the step of forming the recess 5a in the lower surface of the die pad 5 so that the width of the inside of the recess 5a is formed to be larger than the width of the opening of the recess 5a.

Since the width of the inside of the recess 5a is formed to be larger than the width of the opening of the recess 5a, the pawl 19 formed in the opening allows the resin sheet 4 filled into the recess 5a to be hard to detach from the recess 5a. Thus, the contactivity between the lower surface of the die pad 5 and the resin sheet 4 can be improved.

### Second Preferred Embodiment

### Structure

The semiconductor device 100 according to this preferred embodiment is different from the semiconductor device 100 according to the first preferred embodiment in the structure of the recess 5a formed in the lower surface of the die pad 5. Other structure is the same as the first preferred embodiment, and the description thereof is omitted.

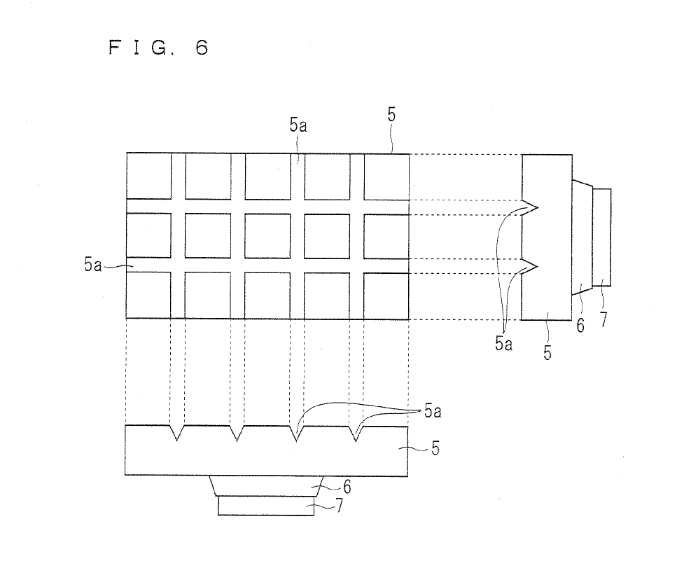

FIG. 6 shows a plan view of the lower surface of the die pad 5 and a side view of the die pad 5 of the semiconductor device 100 according to this preferred embodiment. The semiconductor element 7 is joined to the upper surface of the die pad 5 via the joining portion 6. The lower surface of the die pad 5 is a surface making close contact with the resin sheet 4.

As shown in FIG. 6, the recess 5a extends from one side to the other side of the lower surface of the die pad 5. A plurality of recesses 5a are formed in a lattice shape. In FIG. 6, a path in which each recess 5a extends is straight, but may be curved. The recess 5a is not required to be formed in the lattice shape, and the number of the recess 5a may be one. In this preferred embodiment, the cross-sectional shape of the recess 5a is V-shaped, but may be rectangular or semicircular.

In the process for manufacturing the semiconductor device 100, when the resin sheet 4 is arranged in the mold to arrange the die pad 5 on an upper portion of the resin sheet 4 and the sealing resin 2 is injected into the heated mold for sealing, the solvent in the resin sheet 4 may be volatilized by heating to cause gas.

With the die pad 5 having the structure of this preferred embodiment, the gas passes through the path in which the recess 5a provided in the lower surface of the die pad 5 extends, and is discharged outside of a contact surface between the die pad 5 and the resin sheet 4. That is, the staying of the gas on the contact surface between the die pad 5 and the resin sheet 4 to cause a gap in the contact surface can be prevented.

### Effect

In the semiconductor device 100 according to this preferred embodiment, the recess 5a extends from one side to the other side of the lower surface of the die pad 5.

Therefore, when the semiconductor device 100 is manufactured, the gas generated from the resin sheet 4 passes through the path in which the recess 5a extends, and is discharged from the contact surface between the die pad 5 and the resin sheet 4. That is, the staying of the gas on the contact surface between the die pad 5 and the resin sheet 4 to cause a gap in the contact surface can be prevented. Accordingly, the lowering of the heat conductivity due to the gap caused in the contact surface between the die pad 5 and the resin sheet 4 can be prevented.

### Third Preferred Embodiment

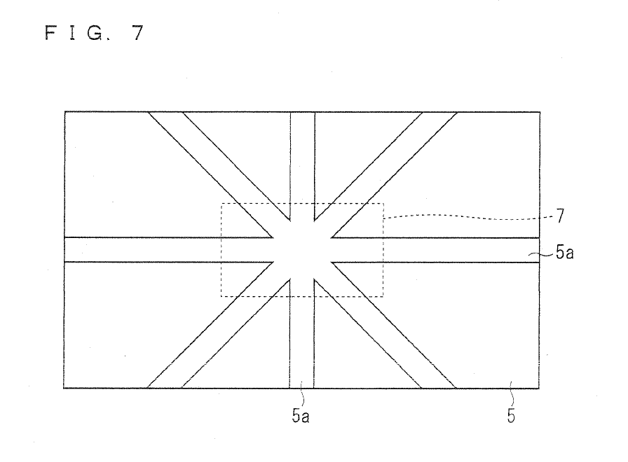

In the semiconductor device 100 according to this preferred embodiment, the structure of the recess 5a in the lower surface of the die pad 5 according to the second preferred embodiment (FIG. 6) is replaced with the structure shown in FIG. 7. Other structure is the same as the first preferred embodiment, and the description thereof is omitted.

In FIG. 7, the recess 5a is provided radially from a region overlapped with the semiconductor element 7 in plan view. The recess 5a extends from one side to the other side of the lower surface of the die pad 5.

When manufacturing the semiconductor device 100, if the semiconductor element 7 is joined to the upper surface of the die pad 5 by solder, for example, the die pad 5 can be convexly warped about the joining portion of the semiconductor element 7 due to a difference in linear thermal expansion coefficient between the semiconductor element 7 and the die pad 5.

With the die pad 5 having the structure of this preferred embodiment (FIG. 7), compression stress onto the warped die pad 5 can be reduced. In addition, when the sealing resin 2 is injected into the mold to press and contact the die pad 5 onto the resin sheet 4 by the pressure of the sealing resin 2, the warp of the die pad 5 can be corrected to be returned to the flat state.

The external heat sink is typically brought into contact with the bottom surface of the semiconductor device 100. However, when the semiconductor element 7 produces heat during operation, the die pad 5 can be convexly warped due to the difference in linear thermal expansion coefficient. When the die pad 5 is convexly warped, the resin sheet 4 making close contact with the lower surface of the die pad 5 and the metal plate 3 are also convexly warped. Consequently, a gap is caused between the bottom surface of the semiconductor device 100 and the external heat sink to deteriorate heat dissipation properties.

With the die pad 5 having the structure of this preferred embodiment (FIG. 7), compression stress onto the warped die pad 5 can be reduced. The warp of the die pad 5 can be reduced to prevent a gap from being caused in a contact surface between the bottom surface of the semiconductor device 100 and the external heat sink.

### Effect

In the semiconductor device 100 according to this preferred embodiment, the recess 5a is provided radially from a region overlapped with the semiconductor element 7 in plan view.

Since the recess 5a formed in the lower surface of the die pad 5 is provided radially from a region overlapped with the semiconductor element 7 in plan view, stress on the die pad 5 when the semiconductor element 7 is joined to the die pad 5 can be reduced to improve the reliability of the joining portion 6. In addition, since the stress on the die pad 5 can be reduced to prevent the warp of the die pad 5, the pressure is uniformly applied onto the resin sheet 4 when the die pad 5 and the resin sheet 4 are brought into close contact with each other. Thus, the thickness of the resin sheet 4 which is in close contact with the die pad 5 can be uniform. Further, since the warp of the die pad 5 is prevented, the warp of the bottom surface of the semiconductor device 100 can be prevented. A gap can thus be prevented from being caused in the contact surface between the bottom surface of the semiconductor device 100 and the external heat sink.

The preferred embodiments can be freely combined, and can be modified and omitted, as needed, in the scope of the present invention.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a die pad;
a semiconductor element joined to an upper surface of said die pad; and
a resin sheet making close contact with a lower surface of said die pad, wherein said semiconductor element is resin-sealed together with said die pad and said resin sheet,
a recess is formed in the lower surface of said die pad, and
a part of said resin sheet is filled into said recess so that said resin sheet makes close contact with the lower surface of said die pad including an inside of said recess.

2. The semiconductor device according to claim 1, wherein a cross section of said recess is V-shaped.

3. The semiconductor device according to claim 1, wherein a width of the inside of said recess is larger than a width of an opening of said recess.

4. The semiconductor device according to claim 1, wherein said recess extends from one side to the other side of the lower surface of said die pad.

5. The semiconductor device according to claim 4, wherein said recess is provided radially from a region overlapped with said semiconductor element in plan view.

6. The semiconductor device according to claim 1, wherein
a heat dissipation filler is mixed into said resin sheet, and
a density of said filler in a portion of said resin sheet filled into said recess is lower than a density of said filler in the rest portion of the resin sheet.

7. The semiconductor device according to claim 1, wherein said semiconductor element is a SiC semiconductor element.

8. A semiconductor device manufacturing method comprising the steps of:
(a) forming a recess in a lower surface of a die pad;
(b) after said step (a), joining a semiconductor element to an upper surface of said die pad;
(c) after said step (b), arranging a resin sheet in a mold held at a temperature at which a sealing resin can be melted to arrange said die pad on an upper surface of the resin sheet; and
(d) after said step (c), injecting the sealing resin into said mold and pressing the lower surface of said die pad onto said resin sheet by a pressure of said sealing resin injected into said mold to fill a part of said resin sheet into said recess so that said resin sheet makes close contact with the lower surface of said die pad including an inside of said recess, and simultaneously, resin-sealing said semiconductor element by said sealing resin together with said die pad and said resin sheet.

9. The semiconductor device manufacturing method according to claim 8, wherein coining is performed a plurality of times in said step (a) so that a width of the inside of said recess is formed to be larger than a width of an opening of said recess.
